(19) United States
(12) Patent Application Publication
(10) Pub. No.: US 2006/0007738 A1
(43) Pub. Date: Jan. 12, 2006

(54) Area management type memory system, area management type memory unit and area management type memory controller

(76) Inventors: Shinji Inoue, Neyagawa City (JP); Takuji Maeda, Neyagawa City (JP); Masayuki Toyama, Neyagawa City (JP); Tomoaki Izumi, Neyagawa City (JP); Masahiro Nakanishi, Yawata City (JP); Shoichi Tsujita, Kyoto City (JP)

Correspondence Address: SMITH PATENT OFFICE, 1901 PENNSYLVANIA AVENUE N W, SUITE 901, WASHINGTON, DC, 20006, US

(21) Appl. No.: 11/175,399

(22) Filed: Jul. 7, 2005

(30) Foreign Application Priority Data
Jul. 9, 2004 (JP) 2004-202851

(51) Int. Cl. G11C 11/34

(52) U.S. Cl. 365/185.08

(57) ABSTRACT

In a storage medium which has a number of areas, access to any area is controlled in accordance with whether or not access to another area is possible, and thereby, destruction of data due to malfunctioning or a wrong operation is prevented. A link control part which controls access to the second area based on the information on access to the first area is provided, and access to the second area is controlled on the basis of whether or not access to the first area is possible. Control becomes possible, such that access to the second area becomes impossible in the state where access to the first area is impossible, while access to the second area becomes possible in the case where access to the first area is possible.

### BACKGROUND OF THE INVENTION

1. Field of the Invention

The present invention relates to an area management type memory system, an area management type memory unit and an area management type memory controller which have a memory area that is logically managed as a number of areas.

2. Discussion of the Related Art

In recent years, copyrighted digital information, such as music contents, have been delivered through communication networks, such as the internet, with the development of multimedia network technology, and one can access to music and the like from anywhere in the world while being at home. Music contents can be stored, for example, in a semiconductor memory card that is connected to a personal computer (hereinafter referred to as “PC”) after being downloaded to the PC, and thereby, music can be played, if necessary, and enjoyed. In addition, a semiconductor memory card where music contents are stored in this manner can be removed from the PC and connected to a portable music reproduction unit, and thereby, one can listen to music while walking. Such a semiconductor memory card is a compact, lightweight, convenient memory unit which incorporates a nonvolatile semiconductor memory, such as a flash memory, having a large memory capacity.

In addition, such a card requires a function for protecting the copyright of the music contents, and methods for implementing this have been proposed. In JP-A 10-340487 (1998), for example, a card comprises a first area for storing encrypted music contents and a second area for storing a key that has been utilized for encrypting the music contents. The first area is an area that can be accessed with a normal access command, and the second area is an area that can be accessed only using a specific method. It is only possible to decode the encrypted music contents correctly in an apparatus into which the specific method has been provided when using such a memory unit, and therefore, it becomes possible to play music data while preventing illegal copying of the music contents.

### SUMMARY OF THE INVENTION

In certain memory units, however, where, though access to the first area can be prohibited in an apparatus in which the first area is not intended to be accessed, access to the second area cannot be prohibited, or conversely, access to the second area cannot be prohibited in an apparatus in which only the first area is intended to be accessed, and thus, a problem arises where a read error occurs due to malfunctioning of the apparatus or a wrong operation by the user who utilizes this, or data is destroyed at the time of write.

The present invention is provided in view of these problems, and an object of the present invention is to prevent the occurrence of a read error and destruction of data by linking the control of access to the first area to the control of access to the second area.

An area management type memory system according the present invention comprises a nonvolatile memory, a host apparatus and a memory controller, wherein said nonvolatile memory has a first area and a second area which are separately managed, said host apparatus accesses said memory controller and requires write and read of data to and from said nonvolatile memory, and said memory controller comprises: a control part which transmits and receives a command and data to and from said host apparatus; a first access control part which controls write and read of data to and from the first area of said nonvolatile memory; a second access control part which controls write and read of data to and from the second area of said nonvolatile memory; a first access information part which stores information for determining whether or not access to the first area of said nonvolatile memory from said host apparatus is possible; a second access information part which stores information for determining whether or not access to the second area of said nonvolatile memory from said host apparatus is possible; and a link control part which determines whether or not access to the second area of said nonvolatile memory is possible on the basis of the information of said first access information part, and conveys the result to said second access control part.

An area management type memory system according the present invention comprises a nonvolatile memory, a host apparatus and a memory controller, wherein said nonvolatile memory has a first area and a second area which are separately managed, said host apparatus accesses said memory controller and requires write and read of data to and from said nonvolatile memory, and said memory controller comprises: a control part which transmits and receives a command and data to and from said host apparatus; a link information part which holds information for indicating a combination of whether or not access to the first area of said nonvolatile memory is possible and whether or not access to the second area of said nonvolatile memory is possible; a first access control part which controls write and read of data to and from the first area of said nonvolatile memory; a second access control part which controls write and read of data to and from the second area of said nonvolatile memory, and determines whether or not access to the second area of said nonvolatile memory is possible on the basis of the information of said first access information part and the information of said link information part; a first access information part which stores information for determining whether or not access to the first area of said nonvolatile memory from said host apparatus is possible; and a second access information part which stores information for determining whether or not access to the second area of said nonvolatile memory from said host apparatus is possible.

An area management type memory system according the present invention comprises a nonvolatile memory, a host apparatus and a memory controller, wherein said nonvolatile memory has a first area and a second area which are separately managed, said host apparatus has a link part which determines whether or not access to the second area of said nonvolatile memory is possible on the basis of whether or not access to the first area of said nonvolatile memory is possible, accesses said memory controller, and requires write and read of data to and from said nonvolatile memory, and said memory controller comprises: a control part which transmits and receives a command and data to and from said host apparatus; a first access control part which controls write and read of data to and from the first area of said nonvolatile memory; a second access control part which controls write and read of data to and from the second area of said nonvolatile memory; a first access information part which stores information for determining whether or not access to the first area of said nonvolatile memory from said host apparatus is possible; and a second access information part which stores information for determining whether or not access to the second area of said nonvolatile memory from said host apparatus is possible.

An area management type memory system according the present invention comprises a nonvolatile memory, a host apparatus and a memory controller, wherein said nonvolatile memory has a first area and a second area which are separately managed, said host apparatus has a link part which determines whether or not access to the second area of said nonvolatile memory is possible on the basis of whether or not access to the first area of said nonvolatile memory is possible, accesses said memory controller, and requires write and read of data to and from said nonvolatile memory, and said memory controller comprises: a control part which transmits and receives a command and data to and from said host apparatus; a link information part which holds information for indicating a combination of whether or not access to the first area of said nonvolatile memory is possible and whether or not access to the second area of said nonvolatile memory is possible; a first access control part which controls write and read of data to and from the first area of said nonvolatile memory; a second access control part which controls write and read of data to and from the second area of said nonvolatile memory; a first access information part which stores information for determining whether or not access to the first area of said nonvolatile memory from said host apparatus is possible; and a second access information part which stores information for determining whether or not access to the second area of said nonvolatile memory from said host apparatus is possible.

An area management type memory unit according the present invention comprises a nonvolatile memory and a memory controller, wherein said nonvolatile memory has a first area and a second area which are separately managed, and said memory controller comprises: a control part which transmits and receives a command and data to and from a host apparatus; a first access control part which controls write and read of data to and from the first area of said nonvolatile memory; a second access control part which controls write and read of data to and from the second area of said nonvolatile memory; a first access information part which stores information for determining whether or not access to the first area of said nonvolatile memory from said host apparatus is possible; a second access information part which stores information for determining whether or not access to the second area of said nonvolatile memory from said host apparatus is possible; and a link control part which determines whether or not access to the second area of said nonvolatile memory is possible on the basis of the information of said first access information part and conveys the result to said second access control part.

An area management type memory unit according the present invention comprises a nonvolatile memory and a memory controller, wherein said nonvolatile memory has a first area and a second area which are separately managed, and said memory controller comprises: a control part which transmits and receives a command and data to and from a host apparatus; a link information part which holds information for indicating a combination of whether or not access to the first area of said nonvolatile memory is possible and whether or not access to the second area of said nonvolatile memory is possible; a first access control part which controls write and read of data to and from the first area of said nonvolatile memory; a second access control part which controls write and read of data to and from the second area of said nonvolatile memory, and determines whether or not access to the second area of said nonvolatile memory is possible on the basis of the information of said first access information part and the information of said link information part; a first access information part which stores information for determining whether or not access to the first area of said nonvolatile memory from said host apparatus is possible; and a second access information part which stores information for determining whether or not access to the second area of said nonvolatile memory from said host apparatus is possible.

An area management type memory controller according the present invention comprises a control part, an access control part, an access information part and a link control part, and which is used for a nonvolatile memory that has a first area and a second area which are separately managed, comprising: a control part which transmits and receives a command and data to and from a host apparatus; a first access control part which controls write and read of data to and from the first area of said nonvolatile memory; a second access control part which controls write and read of data to and from the second area of said nonvolatile memory; a first access information part which stores information for determining whether or not access to the first area of said nonvolatile memory from said host apparatus is possible; a second access information part which stores information for determining whether or not access to the second area of said nonvolatile memory from said host apparatus is possible; and a link control part which determines whether or not access to the second area of said nonvolatile memory is possible on the basis of the information of said first access information part, and conveys the result to said second access control part.

An area management type memory controller according the present invention comprises a control part, a link information part, an access control part and an access information part, and which is used for a nonvolatile memory that has a first area and a second area which are separately managed, comprising: a control part which transmits and receives a command and data to and from a host apparatus; a link information part which holds information for indicating a combination of whether or not access to the first area of said nonvolatile memory is possible and whether or not access to the second area of said nonvolatile memory is possible; a first access control part which controls write and read of data to and from the first area of said nonvolatile memory; a second access control part which controls write and read of data to and from the second area of said nonvolatile memory, and determines whether or not access to the second area of said nonvolatile memory is possible on the basis of the information of said first access information part and the information of said link information part; a first access information part which stores information for determining whether or not access to the first area of said nonvolatile memory from said host apparatus is possible; and a second access information part which stores information for determining whether or not access to the second area of said nonvolatile memory from said host apparatus is possible.

According to the present invention, access to any one of areas can be controlled on the basis of whether or not access to another area is possible in a nonvolatile memory having a number of areas, and the occurrence of read error and destruction of data due to malfunctioning or a wrong operation can be prevented.

### BRIEF DESCRIPTION OF THE DRAWINGS

FIG. 1 is a diagram showing an area management type memory system and unit according to a first embodiment of the present invention;

FIG. 2 is a diagram showing a data example of first access information according to the first embodiment of the present invention;

FIG. 3 is a diagram showing a data example of second access information according to the first embodiment of the present invention;

FIG. 4 is a flowchart showing the area management type memory system according to the first embodiment of the present invention;

FIG. 5 is a diagram showing an area management type memory system and unit according to a second embodiment of the present invention;

FIG. 6 is a flowchart showing the area management type memory system according to the second embodiment of the present invention;

FIG. 7 is a diagram showing an example of link determination information according to the second embodiment of the present invention;

FIG. 8 is a diagram showing an example of link determination information according to the second embodiment of the present invention;

FIG. 9 is a diagram showing an area management type memory system and unit according to a third embodiment of the present invention;

FIG. 10 is a flowchart showing the area management type memory system according to the third embodiment of the present invention;

FIG. 11 is a diagram showing an area management type memory system and unit according to a fourth embodiment of the present invention; and

FIG. 12 is a flowchart showing the area management type memory system according to the fourth embodiment of the present invention.

### DESCRIPTION OF THE PREFERRED EMBODIMENTS

In the following, an area management type memory system, an area management type memory unit and an area management type memory controller of the present invention are described with reference to the drawings.

### First Embodiment

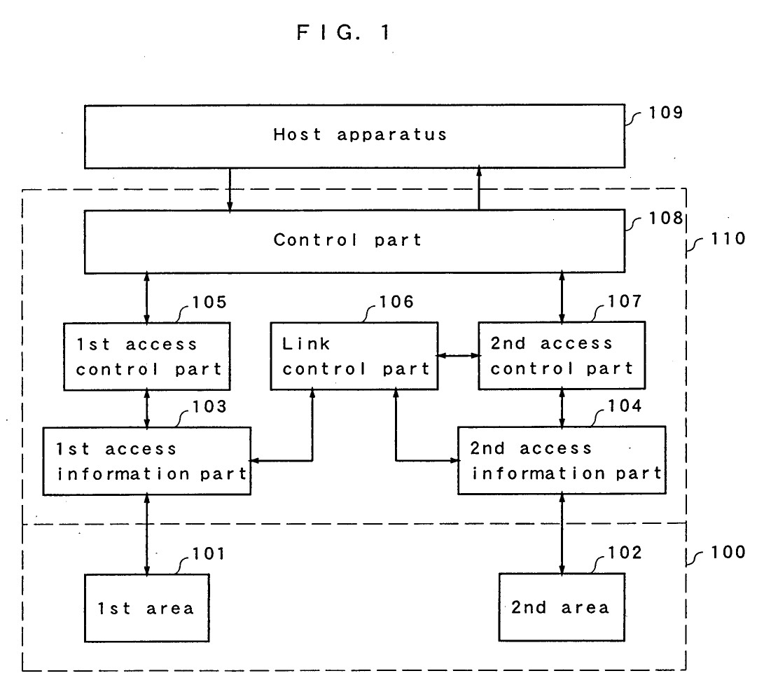

FIG. 1 is a configuration diagram showing an area management type memory system according to a first embodiment of the present invention. The area management type memory system is formed so as to include a nonvolatile memory 100, a host apparatus 109 and a memory controller 110. A first area 101 and a second area 102 are memory areas of the nonvolatile memory 100, where data is managed by means of a file system and the like. The host apparatus 109 requires write or read of data to the nonvolatile memory 100. The memory controller 110 controls reading and writing of data between the host apparatus 109 and the nonvolatile memory 100. A first access information part 103 stores the first access information that is required to access the first area 101 and to determine whether or not access is possible. A second access information part 104 stores the second access information that is required to access the second area 102 and to determine whether or not access is possible. A first access control part 105 controls write and read of data to and from the first area 101 on the basis of the first access information that has been stored in the first access information part 103. A link control part 106 determines whether or not access to the second area 102 is possible on the basis of the first access information, and conveys the result to a second access control part. In the case where access to the first area 101 is permitted or prohibited, access to the second area 102 is permitted and prohibited, respectively. The second access control part 107 controls write and read of data to and from the second area 102 on the basis of the second access information that has been stored in the second access information part 104. A control part 108 accepts a command from a host apparatus 109, and controls the first access control part 105 and the second access control part 107.

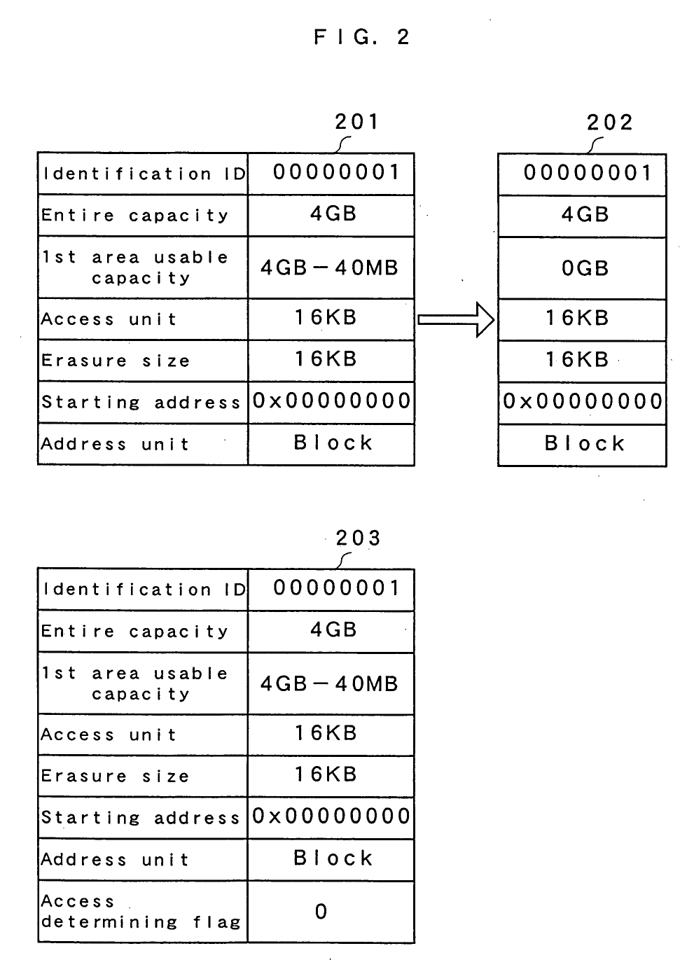

FIG. 2 shows an example of the first access information that is stored in the first access information part 103. In the first access information 201, an identification ID for identifying the area is 00000001, and the entire capacity, including the first area 101 and the second area 102 is 4 GB (bytes). From among this, 4 GB-40 MB is reserved as a first area usable capacity, indicating that the first area is available. In addition, it is indicated that the access unit is 16 KB, the erasure size is 16 KB, the starting address from which access is starting is 00000000, and the address unit is block.

In contrast, in the first access information 202, the first area usable capacity is 0 GB, and the unit of address is block (for example, 512 bytes). This indicates that when the first access information 202 is set in the first access information part 103, where the first area usable capacity is 0 GB, it becomes impossible to access the first area 101. In addition, it indicates that a host apparatus of which the address unit is not block cannot access the first area 101.

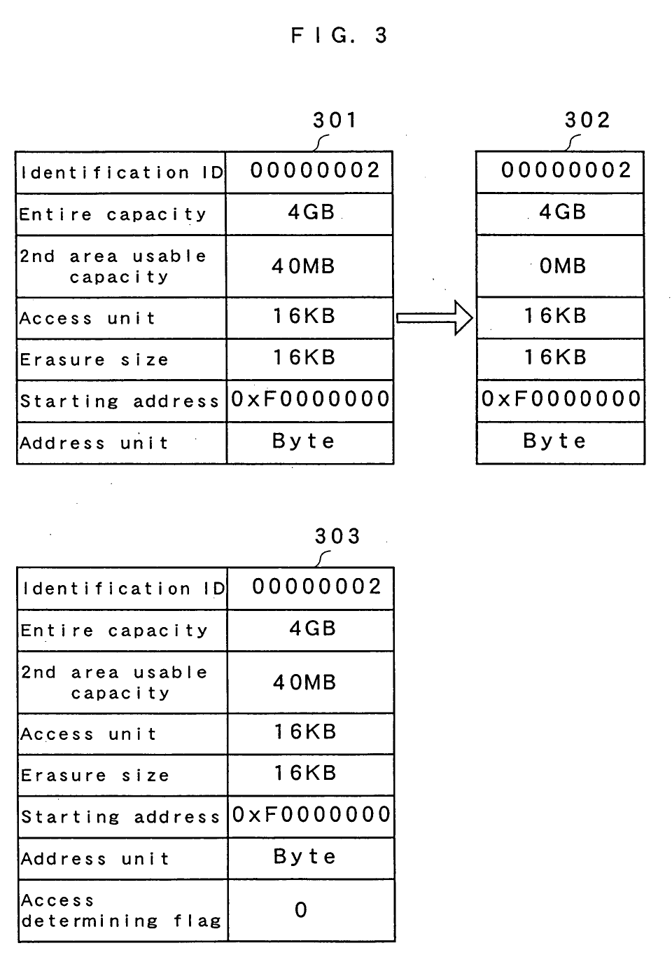

FIG. 3 shows an example of the second access information that is stored in the second access information part 104. In the second access information 301, the ID for identifying the area is 00000002, and the entire capacity, including the first area 101 and the second area 102 is 4 GB. From among this, 40 MB is reserved as a second area usable capacity, indicating that the second area 102 is available. In addition, it is indicated that the access unit is 16 KB, the erasure size is 16 KB, the address from which access is initialized is F0000000, and the unit is bytes.

In contrast, in the second access information 302, the second area usable capacity is 0 MB. This indicates that when the second access information 302 is set in the second access information part 104, where the second area usable capacity is 0 MB, it becomes impossible to access the second area 102.

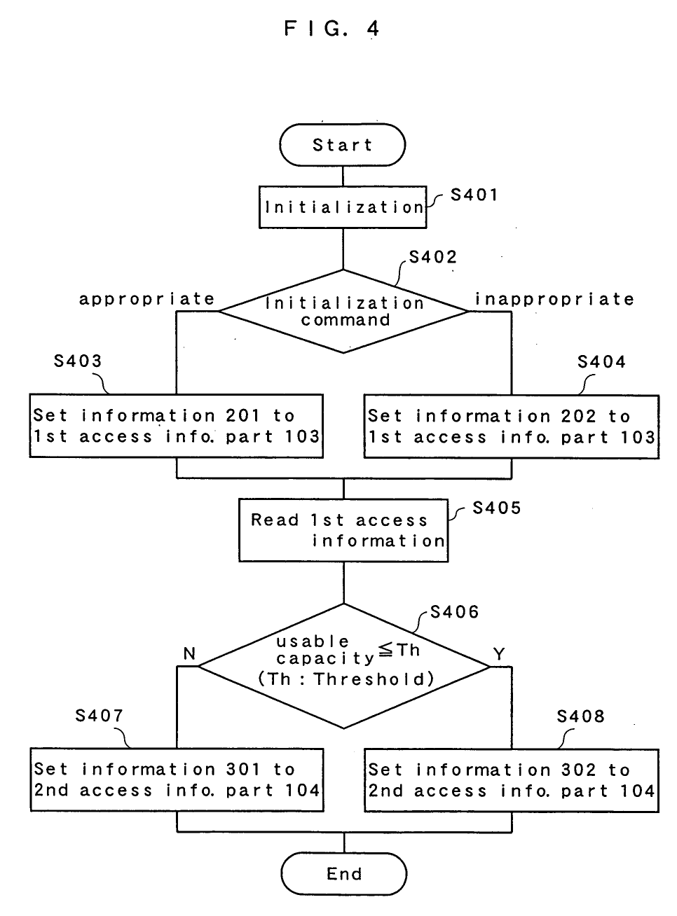

On the basis of the above, the operation of the area management type memory system according to the present embodiment is described, with reference to the flowchart of FIG. 4.

First, when the power supply is turned on, an initialization process is carried out (S401). In the initialization process, the first area 101 and the second area 102 are prepared to be accessed, and subsequently, the first access control part 105 interprets a command from the host apparatus 109, so as to identify the apparatus type of the host apparatus 109 (S402). In the case of an appropriate command that can permit access to the first area 101, the first access information 201 of FIG. 2 is set in the first access information part 103, in order to enable an access to the first area 101 (S403). In contrast, in the case of an inappropriate command that cannot permit access to the first area 101, the first access information 202 of FIG. 2 is set in the first access information part 103, in order to make access to the first area 101 impossible (S404). The second access control part 107 sets the second access information 301 indicating that the second area is reserved, in the second access information part 104.

When the first area 101 is accessed, the first access control part 105 reads in the information of the first access information part 103. In the case where the first access information 201 is set in the first access information part 103, it is possible to access the first area 101 where 4 GB to 40 MB of the first area usable capacity has been reserved, and access is permitted. In contrast, in the case where the first access information 202 is set, it is impossible to access the first area 101 where the first area usable capacity is 0 GB, and access is prohibited. Here, this first area usable capacity can vary on the basis of the total memory capacity of the nonvolatile memory, the amount of data that has been written in, the file system and the like, and is not always 4 GB to 40 MB or 0 GB.

Next, the link control part 106 takes in the first access information of the first access information part 103 (S405). In the case where the first area usable capacity≦Th (Th: threshold value) is not achieved in the first access information that has been read in (S406), the link control part 106 sets the second access information to which access is made possible, in the second access information part 104 (S407). In the case where the second access information 301, for example, is set, the second area usable capacity is 40 MB, and it is possible to access the second area 102. The setting of this second access information 301 may be carried out by the second access control part 107 in compliance with an instruction from the link control part 106.

When the link control part 106 takes in the first access information 202, the first area usable capacity≦Th (Th: threshold value) is achieved (S406), and therefore, the second access information for prohibiting access to the second area 102 is set in the second access information part 104 (S408). In the case where the second access information 302, for example, is set, the second area usable capacity is 0 MB, and access to the second area 102 is prohibited. The setting of this second access information 302 may be also carried out by the link control part 106, or may be carried out via the second access control part 107.

When access to the first area 101 is prohibited in this sequential process, access to the second area 102 is also prohibited. In this case, the control part 108 carries out a process, such as return of an error, even when an access request is sent to any area from the host apparatus 109.

Though according to the present embodiment, whether or not access to the first area 101 is possible is determined by the first area usable capacity of the first access information, whether or not access is possible can be determined in accordance with other methods. An access determining flag may be provided, as in the first access information 203 of FIG. 2. Whether or not access is possible can be determined, by setting an access determining flag in the first access information part 103. Namely, in the case where it is indicated that the access determining flag is “0,” the access is permitted, and in the case where the flag is “1,” the access is prohibited, whether or not access to the first area 101 is possible can be determined without setting the first area usable capacity specifically at 0 GB or the like, leaving the indication of the actual value. Whether or not access to the second area 102 is possible can be determined by setting an access determining flag as in the second access information 303 shown in FIG. 3.

Here, though information of an access determining flag becomes one item in the first or second access information, the same effects can be gained in the case where the access determining flag is held independently apart from the first or second access information.

In a system as described above, linking between the first and second access control parts can be achieved, and as a result, access to the first area and the second area by the host apparatus, which causes a risk of data being destroyed, can be prohibited.

### Second Embodiment

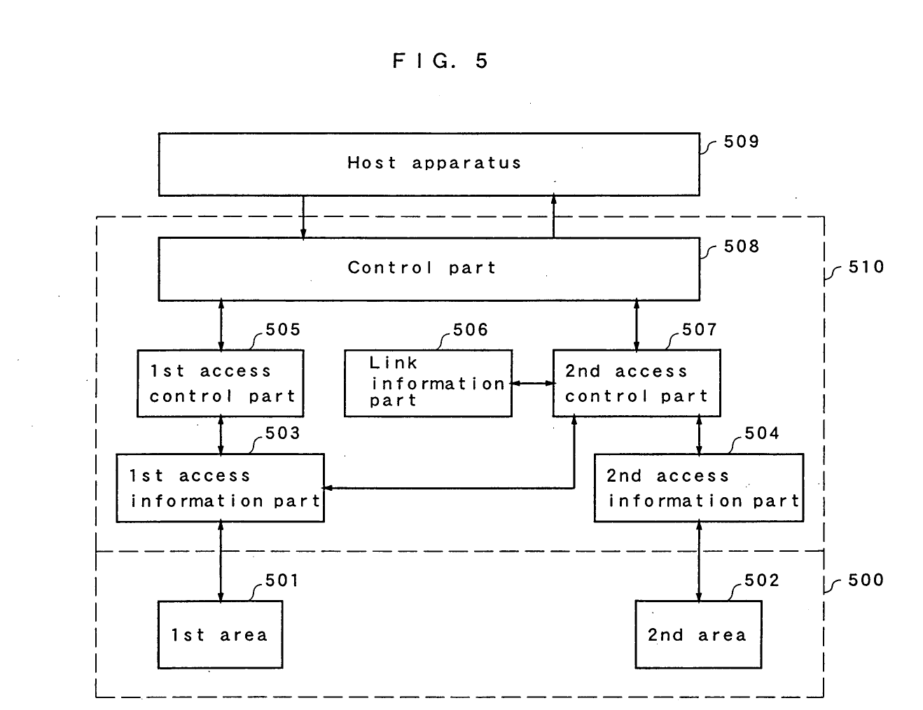

FIG. 5 is a diagram showing the configuration of an area management type memory system according to a second embodiment of the present invention. The area management type memory system is formed so as to include a nonvolatile memory 500, a host apparatus 509 and a memory controller 510. The first area 501 and the second area 502 are memory areas of the nonvolatile memory 500, where data is managed by means of a file system or the like. The host apparatus 509 requests write and read of data to the nonvolatile memory 500. The memory controller 510 controls reading and writing of data between the host apparatus 509 and the nonvolatile memory 500. The first access information part 503 stores the first access information that is required to access the first area 501, and determine whether or not access is possible. The second access information part 504 stores the second access information that is required to access the second area 502, and determine whether or not access is possible. The first access control part 505 controls write and read of data to and from the first area 501 on the basis of the first access information that is stored in the first access information part 503. A link information part 506 holds a combination of whether or not access to the first area is possible and whether or not access to the second area 502 is possible as link information, and conveys this link information to a second access control part 507. The second access control part 507 determines whether or not access to the second area 502 is possible from the first access information and the link information, and controls write and read of data to and from the second area 502 on the basis of the second access information that is stored in the second access information part 504. A control part 508 receives a command from the host apparatus 509 and controls the first access control part 505 and the second access control part 507.

The descriptions of FIGS. 2 and 3 are the same as those of the first embodiment.

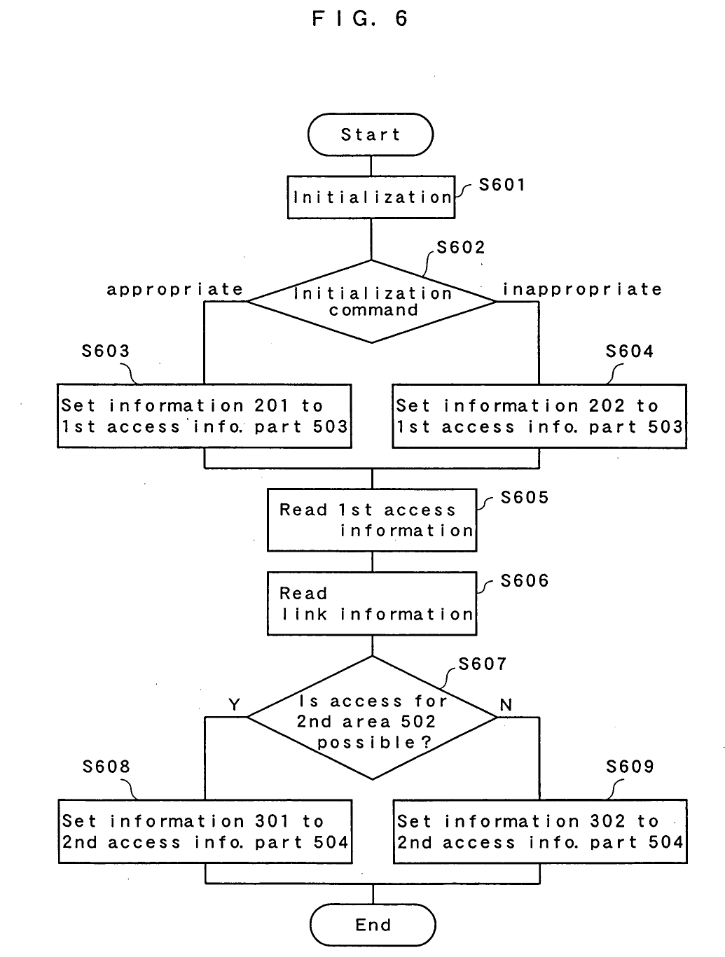

Next, the area management type memory system according to the present embodiment is described with reference to the flowchart of FIG. 6.

First, when the power source is turned on, the process from the initialization to the determination of whether or not access to the first area 501 is possible is carried out in the same manner as in the first embodiment (S601 to S604). After that, the second access control part 507 takes in the first access information from the first access information part 503, and the link information from the link information part 506 (S605 and S606). Subsequently, the second access control part 507 determines whether or not access to the first area 501 is possible and access from the second area 502 from the link information is possible.

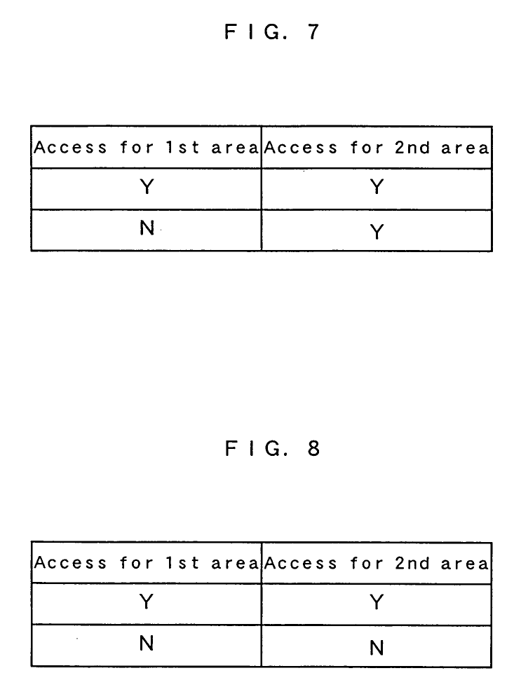

Examples of link information are shown in FIGS. 7 and 8. FIG. 7 shows that access to the second area 502 is possible (Y) in the case where access to the first area 501 is possible (Y), and that access to the second area 502 is possible (Y) even in the case where access to the first area 501 is impossible (N). FIG. 8 shows an example where access to the second area 502 is possible (Y) only in the case where access to the first area 501 is possible (Y). Whether or not access to the second area 502 is possible is determined on the basis of such link information (S607).

In the case where access to the second area 502 is possible, the second access control part 507 sets second access information 301 in the second access information part 504 so as to permit access (S608), while in the case where access to the second area 502 is impossible, the second access control part 507 sets second access information 302 so as to prohibit access to the second area 502 (S609).

Though a combination of whether or not access to the first area 501 and the second area 502 in the link information is determined in advance, according to need of the system, but, if necessary, the combination can be changed from the host apparatus.

In addition, in the present Embodiment, whether or not access to the first area 501 and the second area 502 is possible can be determined using access determining flags, as shown in the first embodiment.

Access to the first and second areas can be controlled using link information as described above, and thereby, access to the first area and to the second area causing a risk of data being destroyed due to malfunctioning or a wrong operation can be prohibited.

### Third Embodiment

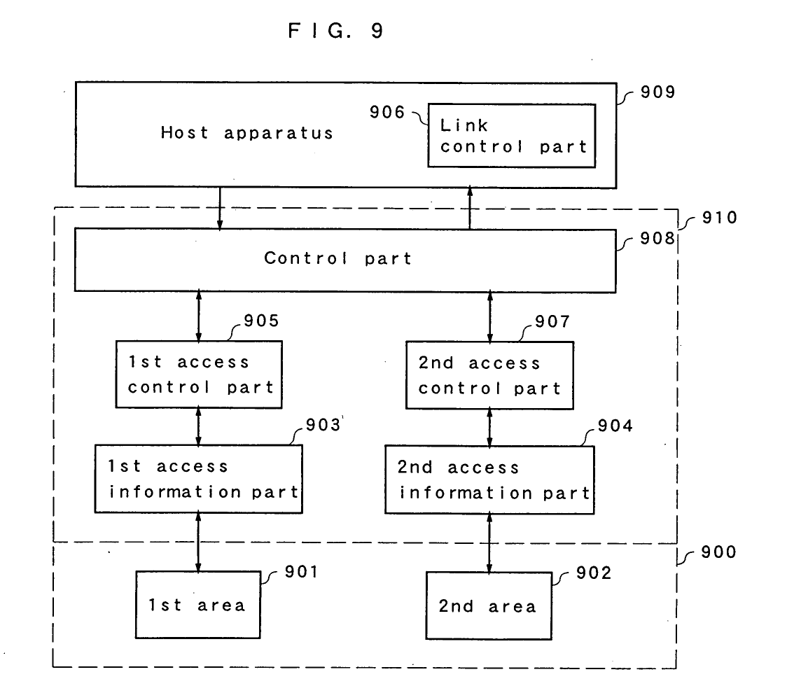

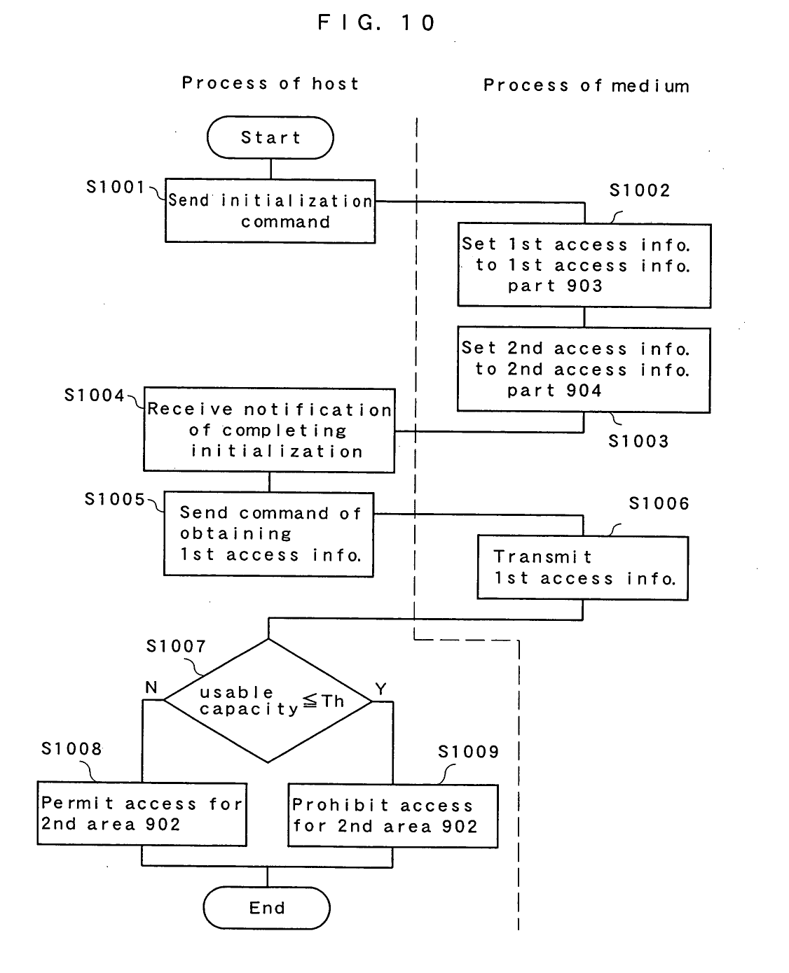

FIG. 9 is a diagram showing the configuration of an area management type memory system according to a third embodiment of the present invention. The area management type memory system is formed so as to include a nonvolatile memory 900, a host apparatus 909 and a memory controller 910. A first area 901 and a second area 902 are memory areas of the nonvolatile memory 900, and a data is managed by means of a file system and the like. The host apparatus 909 requests write and read of data to the nonvolatile memory 900. The memory controller 910 controls reading and writing of data between the host apparatus 909 and the nonvolatile memory 900. A first access information part 903 stores the first access information that is required to access the first area 901 and determine whether or not access is possible. A second access information part 904 stores the second access information that is required to access the second area 902 and determine whether or not access is possible. A first access control part 905 controls write and read of data to and from the first area 901 on the basis of the first access information that has been stored in the first access information part 903. A second access control part 907 controls write and read of data to and from the second area 902 on the basis of the second access information that has been stored in the second access information part 904. A control part 908 receives a command from the host apparatus 909, and controls the first access control part 905 and the second access control part 907.

A link control part 906 determines whether access to the second area 902 is permitted or prohibited in accordance with permission and prohibition, respectively, of access to the first area 901 on the basis of the first access information. In particular, this system determines whether or not access to the second area 902 is possible in the link control part 906 within the host apparatus 909.

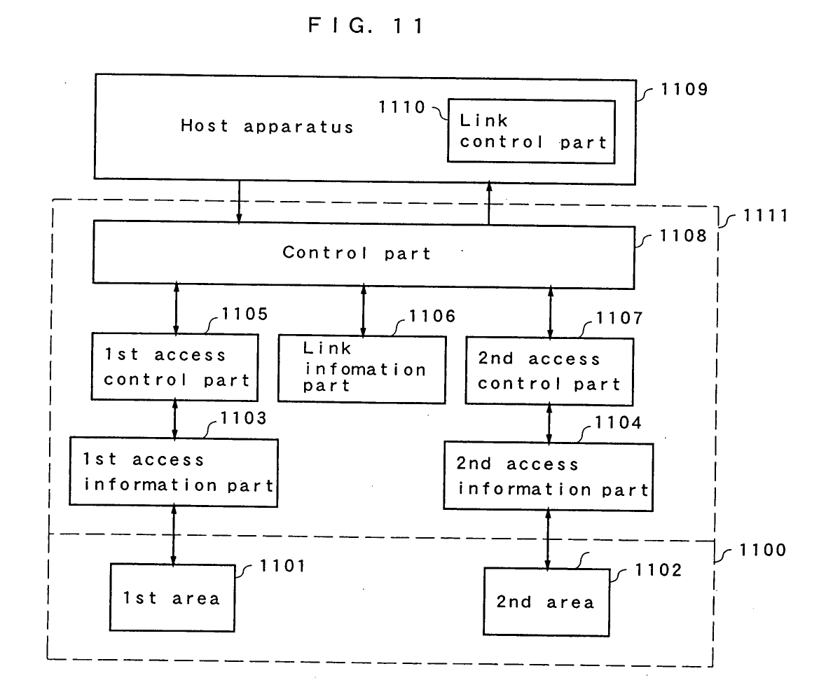

The operation of the area management type memory system is described with reference to the flowchart of FIG. 10. First, when the power supply is turned on, the host apparatus 909 issues an initialization command (S1001). Subsequently, the first access control part 905 interprets the command from the host apparatus 909 so as to identify the type of the host apparatus 909. In the case of an appropriate command that can permit access to the first area 901, the first access information 201 of FIG. 2 is set in the first access information part 903 so as to make access to the first area 901 possible (S1002). In contrast, in the case of an inappropriate command that cannot permit access to the first area 901, the first access information 202 of FIG. 2 is set in the first access information part 903 so as to make access to the first area 901 impossible (S1002). The second access control part 907 sets a second access information 301 that indicates that the second area is reserved, in the second access information part 904 (S1003). Next, the host apparatus 909 is notified of the completion of initialization (S1004), and thus, the initialization is completed.

After that, the host apparatus 909 issues a command for acquiring the first access information (S1005), and the first access information that has been set in the first access information part 903 is sent to the link control part 906 within the host apparatus 909 (S1006). The link control part 906 determines whether or not the first area usable capacity of the first access information becomes the first area usable capacity≦Th (Th: threshold value) (S1007), and permits access to the second area 902, when the capacity is greater than the threshold value (S1008). In contrast, in the case where the capacity is no greater or equal than the threshold value, access to the second area 902 is prohibited (S1009).

Namely, in the case where access to the first area 901 is prohibited, access to the second area 902 is also prohibited, while in the case where access to the first area 901 is permitted, access to the second area 902 is also permitted. After this, the link control part 906 sends either permission or prohibition of access to the second access control part 907, and the second access information that includes whether or not access to the second access information part 904 is possible is set via the second access control part 907, and thereby, access to the second area is controlled. In addition, in the case where, though no information is set in the second access information part 904 in the above manner, the link control part 906 determines prohibition of access to the second area, the similar control of access to the second area can be implemented by not implementing access to the second area on the host apparatus 909 side.

In this manner, even in the case where there is no link control part within the memory controller, it is possible to control access to the first area and second area by connecting the link control part of the host apparatus, and access to the first area or the second area by the host apparatus, which may cause a risk of data being destroyed, can be prohibited.

### Fourth Embodiment

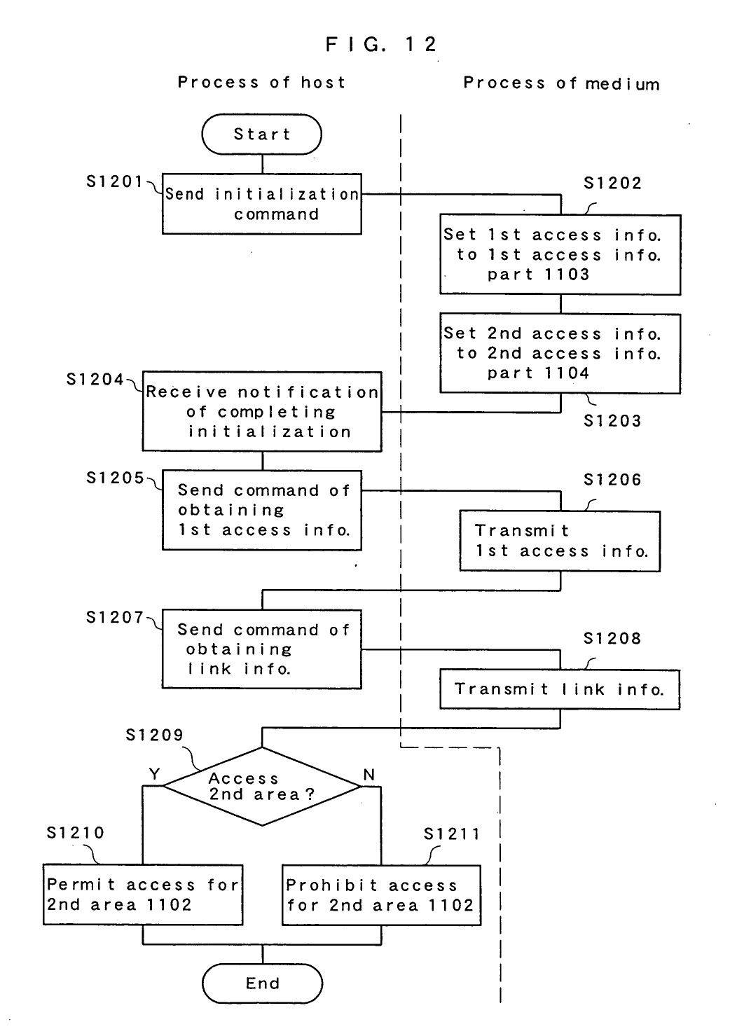

FIG. 11 is a diagram showing the configuration of an area management type memory system according to a fourth embodiment of the present invention. The area management type memory system is formed so as to include a nonvolatile memory 1100, a host apparatus 1109 and a memory controller 1111. A first area 1101 and a second area 1102 are memory areas of the nonvolatile memory 1100, and a data is managed by means of a file system and the like. The host apparatus 1109 requires write and read of data to the nonvolatile memory 1100. The memory controller 1111 controls reading and writing of data between the host apparatus 1109 and the nonvolatile memory 1100. A first access information part 1103 stores the first access information that is required to access the first area 1101 and determine whether or not access is possible. A second access information part 1104 stores the second access information that is required to access the second area 1102 and determine whether or not access is possible. A first access control part 1105 controls write and read of data to and from the first area 1101 on the basis of the first access information that has been stored in the first access information part 1103. A link information part 1106 has a combination of whether or not access to the first area 1101 is possible and whether or not access to the second area 1102 is possible, as link information. The second access control part 1107 controls write and read of data to and from the second area 1102 on the basis of the second access information that has been stored in the second access information part 1104. The control part 1108 receives a command from the host apparatus 1109 and controls the first access control part 1105 and the second access control part 1107.

A link control part 1110 determines whether or not access to the second area 1102 is possible from the first access information and the link information. In particular, this system determines whether or not access to the second area 1102 is possible in the link control part 1110 within the host apparatus 1109.

The operation of the area management type memory system is described with reference to the flowchart of FIG. 12. When the power supply is turned on, the process up to the setting of the first area access information and second area access information is carried out in the same manner as in the third embodiment, and thus, the initialization is completed (S1201 to S1204).

After that, the host apparatus 1109 issues a command for acquiring the first access information (S1205), and the control part 1108 sends the first access information that is set in the first access information part 1103 to the link control part 1110 within the host apparatus 1109 (S1206).

Subsequently, the host apparatus 1109 issues a command for acquiring link information (S1207) and the control part 1108 sends the link information of the link information part 1106 to the link control part 1110 within the host apparatus 1109 (S1208). The link control part 1110 determines whether or not the first area usable capacity≦Th (Th: threshold value) is achieved in terms of the first access information, in the same manner as in the third embodiment, and on the basis of the result and the link information, the link control part 1110 determines whether or not access to the first area 1101 is possible and whether or not access to the second area 1102 is possible (S1209). In the case where access to the first area 1101 is permitted, for example, access to the second area 1102 is permitted when the link information is that shown in FIG. 8. The combination of whether or not access to the first area 1101 and the second area 1102 is possible in the link information is not limited to that shown in FIG. 8, but rather, a combination in accordance with the requirements of the system may be used.

In such an embodiment, it is possible to control access to the first area and the second area by means of the link control part of the host apparatus, and access to the first area or the second area by the host apparatus, which may cause a risk of data being destroyed, can be prohibited.

In all of the above described embodiments, though the first access information is set following the initialization after turning on the power supply, the first access information after the setting may be changed to another setting using the host apparatus, or the link information may be changed using the host apparatus. In addition, the second access control part may include a process that requires security authorization at the time of access to the second area. Furthermore, according to the present invention, even in the case where the first area and the second area use different file systems, or the first area and the second area are made of or consist of different media instead of flash memories according to the present embodiments, area management can be carried out.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims.

The text of Japanese priority application no. 2004-202851 filed on 9 Jul. 2004 is hereby incorporated by reference.

What is claimed is:

1. An area management type memory system comprising a nonvolatile memory, a host apparatus and a memory controller, wherein
said nonvolatile memory has a first area and a second area which are separately managed,
said host apparatus accesses said memory controller and requires write and read of data to and from said nonvolatile memory, and
said memory controller comprises:
a control part which transmits and receives a command and data to and from said host apparatus;
a first access control part which controls write and read of data to and from the first area of said nonvolatile memory;
a second access control part which controls write and read of data to and from the second area of said nonvolatile memory;
a first access information part which stores information for determining whether or not access to the first area of said nonvolatile memory from said host apparatus is possible;
a second access information part which stores information for determining whether or not access to the second area of said nonvolatile memory from said host apparatus is possible; and
a link control part which determines whether or not access to the second area of said nonvolatile memory is possible on the basis of the information of said first access information part, and conveys the result to said second access control part.

2. The area management type memory system according to claim 1, wherein
the first area of said nonvolatile memory and the second area of said nonvolatile memory are different storage medium.

3. An area management type memory system comprising a nonvolatile memory, a host apparatus and a memory controller, wherein
said nonvolatile memory has a first area and a second area which are separately managed,
said host apparatus accesses said memory controller and requires write and read of data to and from said nonvolatile memory, and
said memory controller comprises:
a control part which transmits and receives a command and data to and from said host apparatus;
a link information part which holds information for indicating a combination of whether or not access to the first area of said nonvolatile memory is possible and whether or not access to the second area of said nonvolatile memory is possible;
a first access control part which controls write and read of data to and from the first area of said nonvolatile memory;
a second access control part which controls write and read of data to and from the second area of said nonvolatile memory, and determines whether or not access to the second area of said nonvolatile memory is possible on the basis of the information of said first access information part and the information of said link information part;
a first access information part which stores information for determining whether or not access to the first area of said nonvolatile memory from said host apparatus is possible; and
a second access information part which stores information for determining whether or not access to the second area of said nonvolatile memory from said host apparatus is possible.

4. The area management type memory system according to claim 3, wherein
the information within said link information part can be changed using said host apparatus.

5. The area management type memory system according to claim 3, wherein
the first area of said nonvolatile memory and the second area of said nonvolatile memory are made of different storage medium.

6. An area management type memory system comprising a nonvolatile memory, a host apparatus and a memory controller, wherein
said nonvolatile memory has a first area and a second area which are separately managed,
said host apparatus has a link part which determines whether or not access to the second area of said nonvolatile memory is possible on the basis of whether or not access to the first area of said nonvolatile memory is possible, accesses said memory controller, and requires write and read of data to and from said nonvolatile memory, and
said memory controller comprises:
a control part which transmits and receives a command and data to and from said host apparatus;
a first access control part which controls write and read of data to and from the first area of said nonvolatile memory;
a second access control part which controls write and read of data to and from the second area of said nonvolatile memory;
a first access information part which stores information for determining whether or not access to the first area of said nonvolatile memory from said host apparatus is possible; and
a second access information part which stores information for determining whether or not access to the second area of said nonvolatile memory from said host apparatus is possible.

7. The area management type memory system according to claim 6, wherein
the link part of said host apparatus comprises a link control part which determines whether or not access to the second area of said nonvolatile memory is possible on the basis of the information of said first access information part.

8. The area management type memory system according to claim 6, wherein
the first area of said nonvolatile memory and the second area of said nonvolatile memory are made of different storage medium.

9. An area management type memory system comprising a nonvolatile memory, a host apparatus and a memory controller, wherein
said nonvolatile memory has a first area and a second area which are separately managed,
said host apparatus has a link part which determines whether or not access to the second area of said nonvolatile memory is possible on the basis of whether or not access to the first area of said nonvolatile memory is possible, accesses said memory controller, and requires write and read of data to and from said nonvolatile memory, and
said memory controller comprises:
a control part which transmits and receives a command and data to and from said host apparatus;
a link information part which holds information for indicating a combination of whether or not access to the first area of said nonvolatile memory is possible and whether or not access to the second area of said nonvolatile memory is possible;
a first access control part which controls write and read of data to and from the first area of said nonvolatile memory;
a second access control part which controls write and read of data to and from the second area of said nonvolatile memory;
a first access information part which stores information for determining whether or not access to the first area of said nonvolatile memory from said host apparatus is possible; and
a second access information part which stores information for determining whether or not access to the second area of said nonvolatile memory from said host apparatus is possible.

10. The area management type memory system according to claim 9, wherein
the link part of said host apparatus comprises a link control part which determines whether or not access to the second area of said nonvolatile memory is possible from the information of said first access information part and the information of said link information part.

11. The area management type memory system according to claim 9, wherein
the first area of said nonvolatile memory and the second area of said nonvolatile memory are different storage medium.

12. An area management type memory unit comprising a nonvolatile memory and a memory controller, wherein
said nonvolatile memory has a first area and a second area which are separately managed, and
said memory controller comprises:
a control part which transmits and receives a command and data to and from a host apparatus;
a first access control part which controls write and read of data to and from the first area of said nonvolatile memory;
a second access control part which controls write and read of data to and from the second area of said nonvolatile memory;
a first access information part which stores information for determining whether or not access to the first area of said nonvolatile memory from said host apparatus is possible;
a second access information part which stores information for determining whether or not access to the second area of said nonvolatile memory from said host apparatus is possible; and
a link control part which determines whether or not access to the second area of said nonvolatile memory is possible on the basis of the information of said first access information part and conveys the result to said second access control part.

13. The area management type memory unit according to claim 12, wherein
the first area of said nonvolatile memory and the second area of said nonvolatile memory are made of different storage medium.

14. The area management type memory unit according to claim 12, wherein
the first area of said nonvolatile memory and the second area of said nonvolatile memory use different file systems.

15. The area management type memory unit according to claim 12, which has an authorization procedure for accessing the second area of said nonvolatile memory.

16. An area management type memory unit comprising a nonvolatile memory and a memory controller, wherein
said nonvolatile memory has a first area and a second area which are separately managed, and
said memory controller comprises:
a control part which transmits and receives a command and data to and from a host apparatus;
a link information part which holds information for indicating a combination of whether or not access to the first area of said nonvolatile memory is possible and whether or not access to the second area of said nonvolatile memory is possible;
a first access control part which controls write and read of data to and from the first area of said nonvolatile memory;
a second access control part which controls write and read of data to and from the second area of said nonvolatile memory, and determines whether or not access to the second area of said nonvolatile memory is possible on the basis of the information of said first access information part and the information of said link information part;
a first access information part which stores information for determining whether or not access to the first area of said nonvolatile memory from said host apparatus is possible; and
a second access information part which stores information for determining whether or not access to the second area of said nonvolatile memory from said host apparatus is possible.

17. The area management type memory unit according to claim 16, wherein
the first area of said nonvolatile memory and the second area of said nonvolatile memory are different storage medium.

18. The area management type memory unit according to claim 16, wherein
the first area of said nonvolatile memory and the second area of said nonvolatile memory use different file systems.

19. The area management type memory unit according to claim 16, which has an authorization procedure for accessing the second region of said nonvolatile memory.

20. An area management type memory controller comprising a control part, an access control part, an access information part and a link control part, and which is used for a nonvolatile memory that has a first area and a second area which are separately managed, comprising:
a control part which transmits and receives a command and data to and from a host apparatus;
a first access control part which controls write and read of data to and from the first area of said nonvolatile memory;
a second access control part which controls write and read of data to and from the second area of said nonvolatile memory;
a first access information part which stores information for determining whether or not access to the first area of said nonvolatile memory from said host apparatus is possible;
a second access information part which stores information for determining whether or not access to the second area of said nonvolatile memory from said host apparatus is possible; and
a link control part which determines whether or not access to the second area of said nonvolatile memory is possible on the basis of the information of said first access information part, and conveys the result to said second access control part.

21. The area management type memory controller according to claim 20, which has an authorization procedure for accessing the second area of said nonvolatile memory.

22. An area management type memory controller comprising a control part, a link information part, an access control part and an access information part, and which is used for a nonvolatile memory that has a first area and a second area which are separately managed, comprising:
a control part which transmits and receives a command and data to and from a host apparatus;
a link information part which holds information for indicating a combination of whether or not access to the first area of said nonvolatile memory is possible and whether or not access to the second area of said nonvolatile memory is possible;
a first access control part which controls write and read of data to and from the first area of said nonvolatile memory;
a second access control part which controls write and read of data to and from the second area of said nonvolatile memory, and determines whether or not access to the second area of said nonvolatile memory is possible on the basis of the information of said first access information part and the information of said link information part;
a first access information part which stores information for determining whether or not access to the first area of said nonvolatile memory from said host apparatus is possible; and
a second access information part which stores information for determining whether or not access to the second area of said nonvolatile memory from said host apparatus is possible.

23. The area management type memory controller according to claim 22, which has an authorization procedure for accessing the second area of said nonvolatile memory.
